(19) United States
(12) Patent Application Publication
(10) Pub. No.: US 2022/0029637 A1
(43) Pub. Date: Jan. 27, 2022

(54) METHOD FOR ENCODING AND DECODING LDPC CODE AND COMMUNICATION APPARATUS THEREFOR

(71) Applicant: LG Electronics Inc., Seoul (KR)

(72) Inventors: Kijun JEON, Seoul (KR); Bonghoe KIM, Seoul (KR); Kwangseok NOH, Seoul (KR)

(21) Appl. No.: 17/261,423

(22) PCT Filed: Jul. 27, 2018
(86) PCT No.: PCT/KR2018/008542

§ 371 Date: Jan. 19, 2021

(51) Int. Cl. H03M 13/11; H04L 1/00

(52) U.S. Cl. CPC H03M 13/1111; H04L 1/0061; H03M 13/1134

(57) ABSTRACT

A method for performing low-density parity-check (LDPC) decoding by a communication apparatus may comprise the steps of: acquiring information on a shortening pattern; setting a log-likelihood ratio (LLR) value of a shortening part on the basis of the information on the shortening pattern so as to perform first decoding; and verifying validation of a corresponding codeword on the basis of a result of the first decoding.

### TECHNICAL FIELD

The present disclosure relates to wireless communication and, more particularly, to a method of encoding and decoding low-density parity-check (LDPC) codes and communication apparatus therefor.

### BACKGROUND

Next-generation mobile communication systems beyond 4G assume multipoint cooperative communication, where multiple transmitters and receivers exchange information in a network composed thereof, to maximize information transfer rates and avoid communication shaded areas. According to information theory, in such a communication environment, flexible information transmission over multipoint channels formed in the network may not only increase the transfer rate but also reach the total network channel capacity, compared to when all information is over point-to-point channels. However, it is difficult to design codes capable of achieving the network channel capacity in practical terms, which has not been solved yet. That is, the code design is one of the important challenges to be solved. Thus, it is expected that turbo codes or low-density parity-check (LDPC) codes optimized for point-to-point channels will be still used in communication systems in the near future such as 5G.

In next-generation 5G systems, a wireless sensor network (WSN), massive machine type communications (MTC), etc. has been considered. That is, intermittent transmission of small packets has been considered for massive connections/low costs/low power services.

The connection density requirement of massive MTC services is significantly limited, whereas the data rate and end-to-end (E2E) latency requirements thereof are extremely free (e.g., connection density: up to 200,000/km2, E2E latency: seconds to hours, and DL/UL data rate: typically 1 to 100 kbps).

### SUMMARY

One object of the present disclosure is to provide a low-density parity-check (LDPC) encoding method for a communication device.

Another object of the present disclosure is to provide a LDPC decoding method for a communication device.

Still another object of the present disclosure is to provide a communication device for performing LDPC encoding.

A further object of the present disclosure is to provide a communication device for performing LDPC decoding.

It will be appreciated by persons skilled in the art that the objects that could be achieved with the present disclosure are not limited to what has been particularly described hereinabove and the above and other objects that the present disclosure could achieve will be more clearly understood from the following detailed description.

In one aspect of the present disclosure, a low-density parity-check (LDPC) encoding method for a communication device is provided. The LDPC encoding method may include: generating information; attaching a shortening pattern to the information; and performing LDPC encoding of a sequence of the information to which the shortening pattern is attached. The method may further include transmitting information about the shortening pattern to a receiving side. The method may further include determining the shortening pattern from a shortening pattern set based on features of the information. The features of the information may include a feature about a weight of ones in a bit sequence corresponding to the information.

In another aspect of the present disclosure, a LDPC decoding method for a communication device is provided. The LDPC decoding method may include: obtaining information about a shortening pattern; performing first decoding by configuring a log-likelihood ratio (LLR) value of a shortening part based on the information about the shortening pattern; and verifying validity of a corresponding codeword based on results of the first decoding. The method may further include: when the corresponding codeword is invalid, verifying validity of a partial codeword of the corresponding codeword; reconfiguring the LLR value of sequences of the partial codeword estimated to be valid; and performing second decoding of the corresponding codeword based on the reconfigured LLR value. The method may further include receiving the information about the shortening pattern from a transmitting side. The first and second decoding may be learning-based belief propagation (BP) decoding. The validity of the corresponding codeword may be verified by a syndrome check for the results of the first decoding.

In still another object of the present disclosure, a communication device for performing LDPC encoding is provided. The communication device may include: a processor configured to generate information and attach a shortening pattern to the information; and an LDPC encoder configured to perform the LDPC encoding of a sequence of the information to which the shortening pattern is attached.

The communication device may further include a transmitter configured to transmit information about the shortening pattern to a receiving side. The processor may be configured to determine the shortening pattern from a shortening pattern set based on features of the information. The features of the information may include a feature about a weight of ones in a bit sequence corresponding to the information.

In a further aspect of the present disclosure, a communication device for performing LDPC decoding is provided. The communication device may include: a processor configured to obtain information about a shortening pattern; and an LDPC decoder configured to perform first decoding by configuring an LLR value of a shortening part based on the information about the shortening pattern and verify validity of a corresponding codeword based on results of the first decoding.

The LDPC decoder may be configured to: when the corresponding codeword is invalid, verify validity of a partial codeword of the corresponding codeword; reconfigure the LLR value of sequences of the partial codeword estimated to be valid; and perform second decoding of the corresponding codeword based on the reconfigured LLR value. The communication device may further include a receiver configured to receive the information about the shortening pattern from a transmitting side. The LDPC decoder may be configured to verify the validity of the corresponding codeword through a syndrome check for the results of the first decoding.

According to the present disclosure, when a learning-based decoder based on a shortening pattern method is used, the error floor problem, which is the inherent problem of LDPC codes, may be solved.

It will be appreciated by persons skilled in the art that the effects that could be achieved with the present disclosure are not limited to what has been particularly described hereinabove and other advantages of the present disclosure will be more clearly understood from the following detailed description.

### BRIEF DESCRIPTION OF THE DRAWINGS

The accompanying drawings, which are included to provide a further understanding of the present disclosure and are incorporated in and constitute a part of this specification, illustrate embodiments of the disclosure and together with the description serve to explain the principles of the disclosure.

FIG. 1 is a block diagram illustrating configurations of a base station 105 and a user equipment 110 in a wireless communication system 100.

FIG. 2 is a diagram illustrating a Tanner graph of a parity check matrix.

FIG. 3 is a diagram for explaining modification of H for efficient decoding.

FIG. 4 is a diagram illustrating block error rate (BLER) performance curves (waterfall vs. error floor).

FIG. 5 is a diagram illustrating a parity check matrix (PCM) structure in the prior art and a PCM structure according to the present disclosure.

FIG. 6 is block diagrams of transmitter and receiver sides using a shortening pattern.

FIG. 7 is a flowchart of shortening pattern design for each information sequence.

FIG. 8 is a diagram illustrating input/output and cost functions for determining a learning-based (machine learning based) shortening pattern.

FIG. 9 is a conceptual diagram illustrating design and allocation of a shortening pattern.

FIG. 10 is a diagram for explaining a standard belief propagation (BP) decoding algorithm in a base graph.

FIG. 11 is a diagram for explaining a standard BP decoding algorithm in a base graph.

FIG. 12 is a diagram illustrating deep learning-based BP decoding to calculate weight components of a weighted BP decoder.

### DETAILED DESCRIPTION

Reference will now be made in detail to the preferred embodiments of the present disclosure, examples of which are illustrated in the accompanying drawings. In the following detailed description of the disclosure includes details to help the full understanding of the present disclosure. Yet, it is apparent to those skilled in the art that the present disclosure can be implemented without these details. For instance, although the following descriptions are made in detail on the assumption that a mobile communication system includes the 3GPP LTE and LTE-A systems, the following descriptions are applicable to other random mobile communication systems by excluding unique features of the 3GPP LTE and LTE-A systems.

Occasionally, to prevent the present disclosure from getting vaguer, structures and/or devices known to the public are skipped or can be represented as block diagrams centering on the core functions of the structures and/or devices. Wherever possible, the same reference numbers will be used throughout the drawings to refer to the same or like parts.

Besides, in the following description, assume that a terminal is a common name of such a mobile or fixed user stage device as a user equipment (UE), a mobile station (MS), an advanced mobile station (AMS) and the like. In addition, assume that a base station (BS) is a common name of such a random node of a network stage communicating with a terminal as a Node B (NB), an eNode B (eNB), an access point (AP) and the like.

In a mobile communication system, a UE can receive information from a BS in downlink and transmit information in uplink. The UE can transmit or receive various data and control information and use various physical channels depending types and uses of its transmitted or received information.

Moreover, in the following description, specific terminologies are provided to help the understanding of the present disclosure. In addition, the use of the specific terminology can be modified into another form within the scope of the technical idea of the present disclosure.

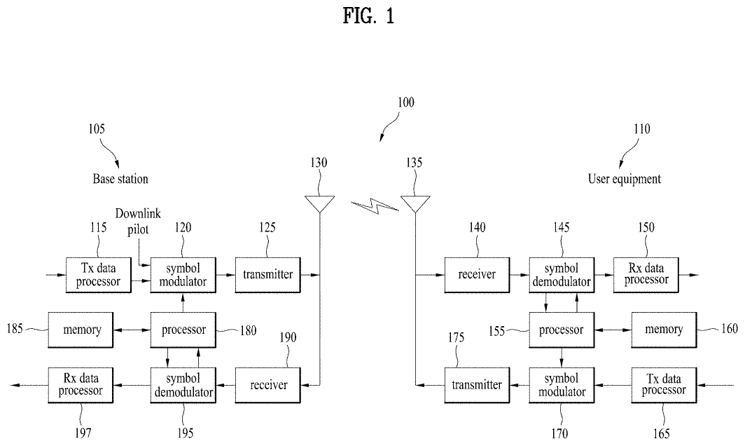

FIG. 1 is a block diagram illustrating configurations of a BS 105 and a UE 110 in a wireless communication system 100.

Although one BS 105 and one UE 110 are shown in the drawing to schematically represent the wireless communication system 100, the wireless communication system 100 may include at least one BSn and/or at least one UE.

Referring to FIG. 1, the BS 105 may include a Transmission (Tx) data processor 115, a symbol modulator 120, a transmitter 125, a transmitting and receiving antenna 130, a processor 180, a memory 185, a receiver 190, a symbol demodulator 195, and a Reception (Rx) data processor 197. The UE 110 may include a Transmission (Tx) data processor 165, a symbol modulator 170, a transmitter 175, a transmitting and receiving antenna 135, a processor 155, a memory 160, a receiver 140, a symbol demodulator 155, and a Reception (Rx) data processor 150. Although FIG. 1 shows that the BS 105 uses one transmitting and receiving antenna 130 and the UE 110 uses one transmitting and receiving antenna 135, each of the BS 105 and the UE 110 may include a plurality of antennas. Therefore, each of the B S 105 and the UE 110 according to the present disclosure can support the Multi-Input Multi-Output (MIMO) system. In addition, the BS 105 according to the present disclosure can also support both of the Single User-MIMO (SU-MIMO) system and the Multi-User-MIMO (MU-MIMO) system.

For downlink transmission, the Tx data processor 115 receives traffic data, formats the received traffic data, codes the formated traffice data, interleaves and modulates (or perform symbol mapping on) the coded traffic data, and provides modulated symbols (data symbols). The symbol modulator 120 provides a stream of symbols by receiving and processing the data symbols and pilot symbols.

The symbol modulator 120 performs multiplexing of the data and pilot symbols and transmits the multiplexed symbols to the transmitter 125. In this case, each of the transmitted symbols may be a data symbol, a pilot symbol or a zero value signal. In each symbol period, pilot symbols may be continuously transmitted. In this case, each of the pilot symbols may be a Frequency Division Multiplexing (FDM) symbol, an Orthogonal Frequency Division Multiplexing (OFDM) symbol, or a Code Division Multiplexing (CDM) symbol.

The transmitter 125 receives the symbol stream, converts the received symbol stream into one or more analog signals, adjusts the analog signals (e.g., amplification, filtering, frequency upconverting, etc.), and generates a downlink signal suitable for transmission on a radio channel. Thereafter, the transmitting antenna 130 transmits the downlink signal to the UE.

Hereinafter, the configuration of the UE 110 is described. The receiving antenna 135 receives the downlink signal from the B S and forwards the received signal to the receiver 140. The receiver 140 adjusts the received signal (e.g., filtering, amplification, frequency downconverting, etc.) and obtains samples by digitizing the adjusted signal. The symbol demodulator 145 demodulates the received pilot symbols and forwards the demodulated pilot symbols to the processor 155 for channel estimation.

The symbol demodulator 145 receives a frequency response estimation value for downlink from the processor 155, performs data demodulation on the received data symbols, obtains data symbol estimation values (i.e., estimation values of transmitted data symbols), and provides the data symbols estimation values to the Rx data processor 150. The Rx data processor 150 reconstructs the transmitted traffic data by demodulating (i.e., performing symbol demapping on), deinterleaving and decoding the data symbol estimated values.

The processing performed by the symbol demodulator 145 and the Rx data processor 150 are complementary to that performed by the symbol modulator 120 and the transmission data processor 115 of the BS 105, respectively.

For uplink transmission, the Tx data processor 165 of the UE 110 processes the traffic data and provides data symbols. The symbol modulator 170 receives the data symbols, performs multiplexing of the received data symbols, modulates the multiplexed symbols, and provides a stream of symbols to the transmitter 175. The transmitter 175 receives the symbol stream, processes the received stream, and generates an uplink signal. The transmitting antenna 135 transmits the generated uplink signal to the BS 105. The BS 105 receives the uplink signal from the UE 110 through the receiving antenna 130. The receiver 190 obtains samples by processing the received uplink signal. Subsequently, the symbol demodulator 195 processes the samples and provides pilot symbols received in uplink and data symbol estimation values. The Rx data processor 197 reconstructs the traffic data transmitted from the UE 110 by processing the data symbol estimation values.

The processor 155 of the UE 110 controls operations (e.g., control, adjustment, management, etc.) of the UE 110, and the processor 180 of the BS 105 controls operations (e.g., control, adjustment, management, etc.) of the BS 105. The processors 155 and 180 may be connected to the memory units 160 and 185 configured to store program codes and data, respectively. Specifically, the memory units 160 and 185, which are connected to the processors 155 and 180, respectively, store operating systems, applications, and general files. Each of the processors 155 and 180 can be called a controller, a microcontroller, a microprocessor, a microcomputer or the like. In addition, the processors 155 and 180 can be implemented using hardware, firmware, software and/or any combinations thereof. When the embodiments of the present disclosure are implemented using hardware, the processors 155 and 180 may be provided with Application Specific Integrated Circuits (ASICs), Digital Signal Processors (DSPs), Digital Signal Processing Devices (DSPDs), Programmable Logic Devices (PLDs), Field Programmable Gate Arrays (FPGAs), etc. Meanwhile, when the embodiments of the present disclosure are implemented using firmware or software, the firmware or software may be configured to include modules, procedures, and/or functions for performing the above-explained functions or operations of the present disclosure. In addition, the firmware or software configured to implement the present disclosure is provided within the processors 155 and 180. Alternatively, the firmware or software may be saved in the memories 160 and 185 and then driven by the processors 155 and 180.

Radio protocol layers between a UE and a BS in a wireless communication system (network) may be classified as Layer 1 (L1), Layer 2 (L2), and Layer 3 (L3) based on three lower layers of the Open System Interconnection (OSI) model well known in communication systems. A physical layer belongs to the L1 layer and provides an information transfer service via a physical channel. A Radio Resource Control (RRC) layer belongs to the L3 layer and provides control radio resources between a UE and a network. That is, a BS and a UE may exchange RRC messages through RRC layers in a wireless communication network.

In the present specification, since it is apparent that the UE processor 155 and the BS processor 180 are in charge of processing data and signals except transmission, reception, and storage functions, they are not mentioned specifically for convenience of description. In other words, even if the processors 155 and 180 are not mentioned, a series of data processing operations except the transmission, reception, and storage functions can be assumed to be performed by the processors 155 and 180.

Overview of Low-Density Parity-Check (LDPC) Code

LDPC codes are one of the most powerful error-correcting codes capable of high-speed data transfer required for next-generation communication systems. In addition, the LDPC codes are designed such that error-correcting capability per bit is improved as the code length increases and decoding can be performed in parallel. That is, the LDPC codes can achieve fast decoding of long codes, which is necessary for the next-generation communication systems. Due to the excellent features, the LDPC codes have been adopted in many standards such as ETSI DVB-S2/C2/T2 for digital broadcasting systems, IEEE 802.16e for WiMAX, IEEE 802.11n for WLAN, IEEE 802.3an for large Ethernet, etc.

The mathematical definition of binary LDPC codes will be described. The LDPC code is a linear code and defined by a parity check matrix H. The parity check matrix has many zeros and a few ones. A set of all codeword vectors c satisfying Hc^{T}=0 for binary operation may be defined as the LDPC code. When the size of the parity check matrix H is m*n, the design code rate may be r=1−m/n.

The LDPC code is often represented by a Tanner graph, which is an equivalent bipartite graph. In the Tanner graph, H is used as the incidence matrix. Each column of H is used as a variable node, and each row thereof is used as a check node. Each of the ones of H is an edge that connects one variable node and one check node. The number of edges connected to one node is the degree of the node. When all variable nodes of an LDPC code have the same degree and all check nodes thereof also have the same degree, the LDPC code is referred to as a regular LDPC code. Otherwise, the LDPC is referred to as an irregular LDPC code.

The following example shows the parity check matrix H of a regular LDPC code having a length of 10, a variable node degree of 3, and a check node degree of 6.

$$H = [ \begin{matrix}1 & 1 & 1 & 1 & 0 & 1 & 1 & 0 & 0 & 0 \\ 0 & 0 & 1 & 1 & 1 & 1 & 1 & 1 & 0 & 0 \\ 0 & 1 & 0 & 1 & 0 & 1 & 0 & 1 & 1 & 1 \\ 1 & 0 & 1 & 0 & 1 & 0 & 0 & 1 & 1 & 1 \\ 1 & 1 & 0 & 0 & 1 & 0 & 1 & 0 & 1 & 1\end{matrix} ]$$

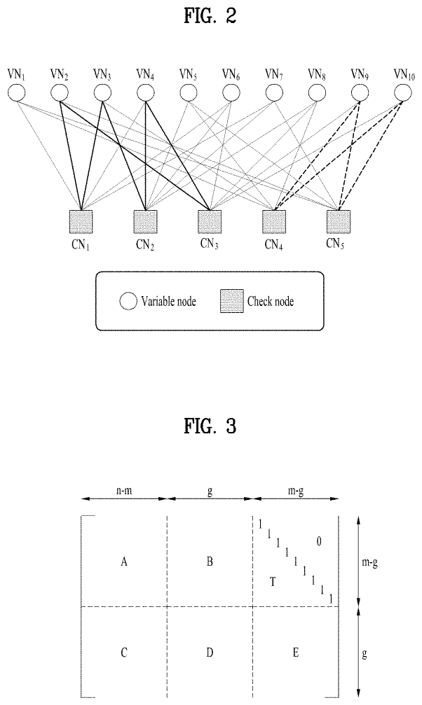

FIG. 2 is a diagram illustrating the Tanner graph of the parity check matrix.

FIG. 2 shows the Tanner graph of the parity check matrix H. In the Tanner graph, a cycle means a path from one node to itself through edges. The length of the shortest cycle is called the girth.

Encoding of LDPC Codes

FIG. 3 is a diagram for explaining modification of H for efficient decoding.

LDPC codes may be encoded via a generator matrix. However, such encoding may involve an increase in complexity. The reason for this is that even though the density of the parity check matrix is low, the density of the generator matrix is not low. For use in communication systems, low-complexity encoding is required. Thus, in this section, an efficient encoding method proposed by Richardson will be described.

An m*n parity check matrix H may be always represented as shown in FIG. 3, using row-wise and column-wise permutations. Since H is modified only by the permutations, it may keep the low-density feature. T may have a lower triangular form where diagonal elements are all ones. By multiplying H of FIG. 3 by

$$[ \begin{matrix}I & 0 \\ - {ET}^{- 1} & I\end{matrix} ] , \\ H = [ \begin{matrix}A & B & T \\ - {ET}^{- 1} A + C - & {ET}^{- 1} B + D & 0\end{matrix} ]$$

may be obtained.

When the codeword c is represented by c=[s p₁, p₂] using a message vector s with a length of n−m, a parity vector p₁ with a length of g, which is located at the front, and a parity vector p₂ with a length of n−m, which is located at the rear, the following equation may be obtained from Hc^{T}=0.

As^{T}+Bp₁^{T}+Tp₂^{T}=0

(−ET⁻¹A+C)s^{T}+(−ET⁻¹B+D)p₁^{T}=0

A matrix ϕ with a size of g*g is defined by ϕ=−ET⁻¹B+D. In general, since ϕ is a nonsingular matrix and g has a small value, ϕ⁻¹ may be calculated with low complexity. Thus, if the message vector s is given, p₁ and p₂ may be efficiently decoded as follows.

p₁^{T}=−ϕ⁻¹(−ET⁻¹A+C)s^{T}

p₂^{T}=−T⁻¹(As^{T}+Bp₁^{T})

Decoding of LDPC Codes

The greatest benefit of LDPC codes is that the decoding complexity is proportional to the code length due to low density and iterative decoding. There are various LDPC code decoding methods. In this section, message-passing iterative decoding, which is theoretically optimal and widely used, will be described. The message-passing iterative decoding may mean a series of processes where nodes in the Tanner graph exchange messages based on information received on channels and then estimate the original codeword. The probabilistic estimation through message transfer in a graph with no cycles is well developed theoretically, and thus an optimal algorithm therefor may be implemented. However, since the length of an LDPC code used in real systems is hundreds or tens of thousands, the LDPC code may include a number of cycles. The probabilistic estimation through message transfer in a graph with cycles has not been solved theoretically. However, since it has been experimentally verified that sufficiently good results can be obtained if a message transfer algorithm derived from a graph with no cycles is applied to an LDPC code with a limited code length, the algorithm has been used in real systems.

Hereinafter, belief propagation (BP) decoding which applied when a received value is soft decision data will be described in brief. For convenience of description, it is assumed that a regular code has a variable node degree of dᵥ and a check node degree of d_{c}. In the BP decoding, the following log likelihood ratio (LLR) is used as a message

$$( m = log \frac{{p}_{i}}{{p}_{- i}} ) ,$$

where pᵢ denotes the probability that a transmitted value of a variable node related to the corresponding message is j (where j=1 or −1). Thus, the sign and absolute value of the message may represent the transmitted value of the corresponding variable node and the reliability thereof, respectively.

The present disclosure provides a learning-based decoder based on a shortening pattern method to solve the error floor problem, which is the inherent problem of LDPC codes with good waterfall characteristics.

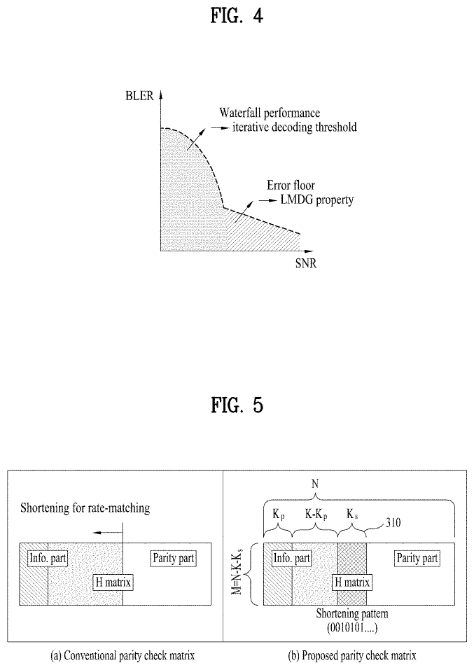

FIG. 4 is a diagram showing block error rate (BLER) performance curves (waterfall vs. error floor).

Generally, the BLER performance of an LDPC code is determined by waterfall characteristics and error floor characteristics. Those characteristics are separately placed in the degree distribution of a parity check matrix (PCM). To achieve good waterfall characteristics, the following three conditions need to be satisfied: 1) there are a few high-degree variable nodes (VNs) (i.e., columns in PCM); 2) there are many degree-1 VNs; and 3) there are several degree-2 VNs. Although a linear block code satisfies the above degree distribution conditions, the linear block code has poor error floor characteristics because it does not satisfy the linear minimum distance growth (LMDG) property.

To achieve good error floor characteristics, the degree of every VN needs to be greater than or equal to 3, a parity VN part needs to be recursively configured with at least two accumulators (i.e., degree-3 or higher VNs and degree-2 VNs coexist in views of the PCM), or an information VN part needs to be input to the corresponding accumulators with at least three repetitions so that sufficient interleaver gain should be guaranteed. However, even if an LDPC code satisfies the above-described conditions, the LDPC code may violate the best condition regarding the waterfall characteristics, That is, there may be a loss in the iterative decoding threshold, thereby degrading the waterfall performance. In addition, if the degree of every VN is greater than or equal to 5, encoding may be performed only by a generator matrix. Due to the high density of the generator matrix, efficient encoding is disabled with linear complexity.

In addition to designing a good LDPC code, residual bit errors may be corrected using another linear block code as an outer code so that the error floor may be improved. However, such two-step coding may decrease the effective code rate, thereby decreasing the waterfall performance of a target code rate.

As described above, it is difficult to design an LDPC code that satisfies good waterfall and error floor characteristics at the same time. Accordingly, the present disclosure proposes a device structure and encoder/decoder method for using shortening in new ways to improve the error floor characteristics of an LDPC code having good waterfall characteristics.

LDPC Code Decoder Issue

Generally, a message-passing decoder is used to decode linear block codes. Depending on the key performance indicator (KPI) (performance or hardware complexity) of a decoder, a BP (i.e., sum product) algorithm or min-sum algorithm is selected and used. In the case of a standard message-passing decoder, it is assumed that a check-to-variable (C2V) message has the same reliability as that of a variable-to-check (V2C) message. However, since a real PCM has irregular degree distribution, each message has different reliability. Since the current standard message-passing decoder does not consider the above feature, it may not guarantee the best performance.

If the message-passing decoder is implemented by giving priority to a highly reliable message in consideration of the reliability of each message, the performance thereof may be improved. Short Bose-Chaudhuri-Hocquenghem (BCH) codes have been researched to improve the performance of decoders based on similar approaches. However, it is only applicable to very short linear block codes. The present disclosure proposes a learning-based decoder method applicable to quasi-cyclic (QC) LDPC codes.

Hereinbelow, the present disclosure will be described in four main sections: (1) PCM based on shortening pattern; (2) encoder/decoder structure based on shortening pattern; (3) learning-based shortening pattern determination; and (4) learning-based QC-LDPC code decoder. In addition, the present disclosure provides the whole flowcharts of transmitter and receiver sides and the concept of each block. In sections (3) and (4), a method of designing the shortening pattern described in section (2) through on learning and a method of designing a learning-based decoder will be described. The learning described herein means a deterministic method that does not require periodic training in offline mode.

Before describing the details of the present disclosure, the following notations are defined. Regular characters denote scalars. Bold lowercase and uppercase characters denote vectors and matrices, respectively. Calligraphic characters denote sets. For example, x, x, X, and [symbol] denote a scalar, a vector, a matrix, and a set, respectively. In addition, w(u,v)=∥u−v∥₁ denotes XOR operation of binary vectors u and v. ∥•∥₁ and ∥•∥₂ denote l₁ norm and l₂ norm, respectively. |X| denotes the cardinality of set X.

(1) Parity Check Matrix (PCM) Structure Based on Shortening Pattern

First, typical shortening will be described. In general, shortening is used for rate matching, that is, to transmit information bits shorter than the information bits of a given PCM. Specifically, some information bits to be shortened are zero-padded. The corresponding bits are processed as known bits by the receiver side (that is, the LLR value of the corresponding bit is set to be infinite and then decoded by the decoder).

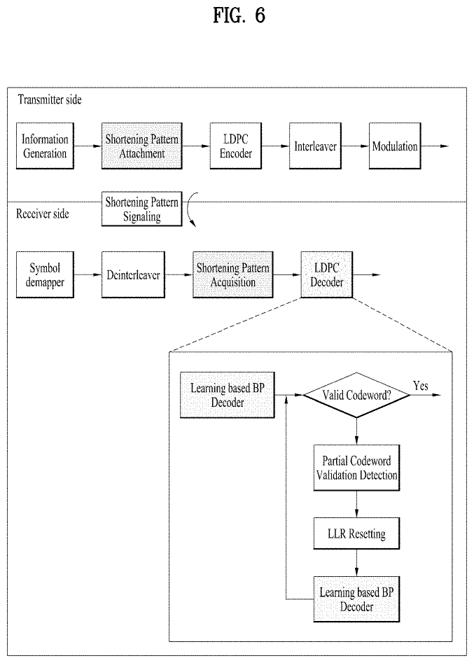

FIG. 5 is a diagram showing a PCM structure in the prior art and a PCM structure according to the present disclosure.

In contrast to the conventional shortening approach, the present disclosure proposes that the receiver side (or receiving side) validates the detection of a partial codeword based on a shortening pattern defined by a binary sequence including information features, thereby improving the performance of the decoder. A new PCM structure for using the shortening pattern will be described first, and then a shortening pattern design and a learning-based BP (LBP) decoder will be described in detail later. The shortening pattern proposed in the present disclosure may be a sequence having binary values of ‘0’ and ‘1’ rather than all zeros.

FIG. 5 (a) shows the structure of the conventional PCM. If necessary, specific bits are zero-padded starting from the information tail bit and then processed as known bits. FIG. 5 (b) shows the PCM structure based on the shortening pattern according to the present disclosure. The newly added artificial columns in the black area 310 of FIG. 5 (b) is a region to which a shortening pattern sequence is allocated. The weight of ones in the corresponding region of the PCM needs to be dense as much as possible. The reason for this is that the shortening pattern sequence does not affect parity generation only when ones are present in the corresponding columns. Since the shortening pattern sequence is processed as known bits by the receiver side (or receiving side), it may not be transmitted to the transmitter side (or transmitting side), whereby it does not affect to the waterfall performance. However, since it affects the parity generation, a codeword distance may be improved. In this case, the code rate may be defined by

$$R = \frac{K}{N - {K}_{s} - {K}_{p}} ,$$

where K denotes the length of an information sequence, Ks denotes the length of the shortening pattern sequence, Kp denotes the length of a punctured information sequence, and N denotes the total column length of the PCM. Compared to the conventional PCM structure shown in FIG. 5 (a), the PCM structure shown in FIG. 5 (b) further requires a matrix with a length of Ks (the length of the shortening pattern sequence) to obtain the matrix H.

(2) Encoder/Decoder Structure Based on Shortening Pattern

The shortening pattern design and LBP decoder will be described in detail in the following sections: (2) encoder/decoder structure based on shortening pattern; and (3) learning-based shortening pattern determination. Hereinafter, the operations of the transmitter/receiver side will be described on the assumption that a specific shortening pattern and LBP decoder are given.

FIG. 6 shows block diagrams of the transmitter and receiver sides using the shortening pattern.

The operations of the transmitter side will be described with reference to FIG. 6. The transmitter side selects a specific shortening pattern from a set of shortening patterns based on the feature of an information bit sequence (for example, the weight of ones in the sequence) according to a shortening pattern determination rule (which will be described in detail later), attaches the selected shortening pattern, and then performs LDPC encoding of the shortening pattern attached information sequence. The shortening pattern may improve the minimum distance between information bit sequences according to the shortening pattern determination rule (for example, different shortening patterns are allocated to adjacent information sequences). The transmitter side may perform interleaving on bits encoded by an LDPC encoder and modulate the interleaved bits.

The operations of the receiver side will be described with reference to FIG. 6.

The receiver side may perform the following operations: 1) acquisition of a shortening pattern; 2) first decoding; 3) verification of whether a codeword is valid; and 4) second decoding. The transmitter side may signal information about the shortening pattern over a physical control channel, and the receiver side may obtain the information about the shortening pattern.

The receiver side may configure the LLR value of a shortening part based on the shortening pattern information and perform first decoding using the LBP decoder. The receiver side may validate the corresponding codeword by performing a syndrome check for the output of the decoder. If the codeword is invalid, the receiver side may validate a partial codeword (a part of information) based on the shortening pattern (for example, if a part of the shortening pattern is determined to be dependent on a part of the partial codeword, the receiver side may anticipate the validity of the corresponding partial codeword). After validating the partial codeword, the receiver side may reconfigure the LLR of partial codeword sequences estimated to be valid. The receiver side may perform second LBP decoding based on the reconfigured LLR. The second decoding based on the shortening pattern may improve the error floor by correcting residual bit errors. It may be considered that outer coding is performed without any loss in the code rate.

Before describing the shortening pattern determination rule depending on the features of the information bit sequence, the concept of the shortening pattern design will be described in brief.

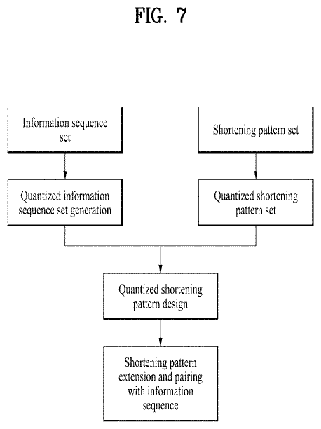

FIG. 7 is a flowchart of the shortening pattern design for each information sequence.

First, since the size of a search space extremely increases if all information sequence sets are handled, the search space is quantized into partial vectors. The partial vectors are determined as training sequence sets, and then a quantized shortening pattern corresponding to each quantized information sequence is determined. When the number of quantized shortening patterns is limited, the quantized shortening pattern may correspond to multiple quantized information sequences.

After mapping between quantized information sequences and quantized shortening patterns, an information sequence and a shortening pattern related thereto may be determined. That is, the shortening pattern may be determined based on the weight of ones in the information sequence. For example, Q shortening patterns may be generated from one quantized shortening pattern. A specific shortening pattern is selected from among the Q shortening patterns depending on a value obtained by applying Q-modulo operation to the weight of ones of an information sequence generated from a quantized information sequence. FIG. 7 shows the above process.

The encoder according to the present disclosure is different from the conventional encoder in that not only the information sequence but the shortening pattern sequence are used for the parity generation according to the redefined PCM.

For example, a device including the shortening pattern-based encoder/decoder according to the present disclosure may be necessarily used for a use case for 5G communication, for example, Ultra-Reliable Low-Latency Communication (URLLC). It is expected that LDPC codes currently used for Enhanced Mobile Broadband (eMBB) services will also be used for URLLC services due to common hardware advantages. However, since the standard encoder/decoder does not have good error floor characteristics, there will be problems in providing the URLLC services (in the case of the URLLC services, reliability of up to 10⁻⁹ is required for each user case, and the error floor problem is not simply solved by an increase in the reception sensitivity).

The features of the transmitter/receiver side having the PCM and encoder/decoder structure based on the above-described shortening pattern may be summarized as follow:

1. A new PCM structure including artificial columns for using the shortening pattern is proposed.

2. The transmitter/receiver side may include a memory for storing a modified PCM in consideration of the use of the shortening pattern.

3. The processor of the transmitter/receiver side may determine the shortening pattern based on the features of information.

4. The transmitter side may include an encoder for performing encoding based on the information and shortening pattern.

5. The transmitter side may include a control channel (information) generator for adding a control channel to provide a control signal mapped to the shortening pattern.

6. The processor of the receiver side may obtain the shortening pattern from a received control channel.

7. The processor of the receiver side may configure an LLR based on the obtained shortening pattern.

8. The decoder (processor) of the receiver side may perform first message-passing decoding based on an (initial) LLR.

9. The processor of the receiver side may determine the validity of a partial codeword based on the shortening pattern.

10. The processor of the receive side may reconfigure the LLR on the ground of the partial codeword validation, and the decoder may perform second message-passing decoding based on the reconfigured LLR.

(3) Learning-Based Shortening Pattern Determination Rule

The shortening pattern may affect the minimum distance between shortening pattern attached information bit sequences and also affect bit error performance. Thus, it is important to precisely design the shortening pattern and properly allocate the shortening pattern to each information sequence to achieve shortening pattern based decoding. Determining a fixed number (Nₛ) of optimal shortening patterns in consideration of control overhead (i.e., the number of bits for indicating the shortening pattern) may represented as follows.

[symbol]

=argmax [symbol] min [symbol] {w(rᵢ,rⱼ) for ∀i,j and i≠j} [Equation 1]
In Equation 1, [symbol] ={sᵢ}ᵢ₌₁²^{^{K}} and [symbol] =(pᵢ)ᵢ₌₁²^{ₖ}ₛ denote all possible information sequence sets with a length of K and all possible shortening pattern sequence sets with a length of Ks, respectively. sᵢ and pᵢ denote an i-th information sequence and an in-th shortening pattern, respectively. rᵢ=[sᵢ,p_{c(l)}] denotes an i-th shortening pattern attached information sequence, and p_{c(l)} denotes a shortening pattern allocated to an i-th information sequence. Shortening pattern attached information sequence sets [symbol] and [symbol] denote information sequence sets with the length of K and Nₛ selected shortening pattern sets, and [symbol] ={rᵢ=[sᵢ,p_{c(l)]}} [symbol] _{denotes a subset of} [symbol] _{including shortening patterns with the length of Ks. Since the numbers of possible information sequences and shortening pattern with the lengths of K and Ks are extremely large, i.e.,} 2^{K} and 2^{Ks}, respectively, this may be relaxed as shown in Equation 2.

[symbol]

=argmax [symbol] min [symbol] {w(r̅ᵢ,r̅ⱼ) for ∀i,j and i≠j} [Equation 2]

In Equation 2, r̅ᵢ=[s̅ᵢ,p̅_{c(l)}] denotes an ith shortening pattern attached information sequence, [symbol] and [symbol] denote quantized information sequence sets and possible quantized shortening pattern sets with lengths of K̅(=K/Q) and K̅ₛ(=Kₛ/Q). [symbol] denotes selected quantized shortening pattern sets, and the number thereof is N̅ₛ(≤Nₛ). Various quantization methods may be applied. For example, a quantized information sequence with the length of K̅ may be determined by the weight portion of ones of a partial sequence with a length of Q. However, even though the above relaxation is performed, the corresponding problem may not be solved because the objective function of Equation 2 is not convex. Thus, the present disclosure uses learning to solve the above optimization problem.

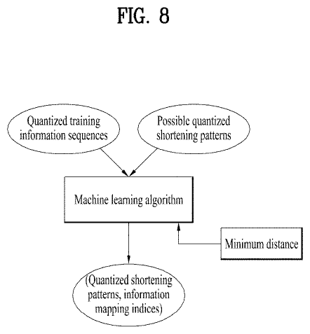

FIG. 8 shows input/output and cost functions for determining a learning-based (machine learning based) shortening pattern.

As the input for learning, a quantized training information sequence set and a (possible) quantized shortening pattern sequence set are used. A machine learning algorithm is applied to the input for learning to calculate the output. The output contains a desired number of quantized shortening pattern sequence sets and the mapping index of each quantized information sequence. The minimum distance between shortening pattern attached information sequences increases because the minimum distance is used as the cost function during learning, which improves the minimum distance of the codeword.

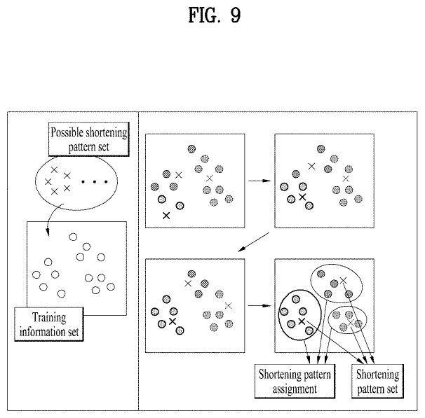

FIG. 9 is a conceptual diagram illustrating the design and allocation of the shortening pattern.

The problem to be solved in the present disclosure is an unsupervised learning method because a training set is composed of only input data. In addition, a method of designing a quantized shortening pattern and mapping the shortening pattern to each quantized information sequence may be regarded as a problem equivalent to the clustering method.

Each information sequence and shortening patterns may be viewed as location tuple information and cluster representative values. Assigning each information sequence to a shortening pattern may be equal to mapping each location tuple belonging to a cluster to a representative value thereof. The learning-based shortening pattern design process follows a training process shown in Table 1 below. Table 1 shows the training algorithm for the shortening pattern design.

```
TABLE 1
Input: [symbol]     = [0,1] [symbol]   , [symbol]    = [0,1] [symbol]   ,
Output: [symbol]
Initialization: Arbitrarily construct [symbol]     by collecting selected N̅ₛ sequences within [symbol]
for l=1, . . . , L do
  Shortening pattern assignment step
  c^{(l)} = max_{c}J(c,p̅ [symbol]   , . . . ,p̅ [symbol]   ) holding p̅ [symbol]   , . . . , p̅ [symbol]    fixed
  where J(c,p̅ [symbol]   , . . . , p̅ [symbol]   ) = mi [symbol]   w(r̅ᵢ, r̅ⱼ),c = [c(1), . . . ,c(| [symbol]   |)] and r̅ᵢ = [s̅ᵢ, p̅_{c(i)}]
  Shortening pattern selection step
  [p̅ [symbol]   , . . . , p̅ [symbol]   ] = ma [symbol]   J(c^{(l)}, p̅ [symbol]   , . . . , p̅ [symbol]   ) holding c^{(l)} = [c^{(l)}(1), . . . , c^{(l)}(| [symbol]   |)] fixed
end
Set [symbol]     = {r̅ᵢ} [symbol] [symbol] [symbol]        = {p̅ [symbol]   } [symbol] [symbol]
indicates data missing or illegible when filed
```

In Table 1, is a layer l index, and J(c, p̅₂, . . . , p̅_{N̅}_{ₛ} the cost function. Once the quantized shortening pattern is determined through the above process, each quantized shortening pattern may be divided into B(=Nₛ/N̅ₛ) shortening patterns depending on the properties of information sequences (for example, depending on whether the number of ones is odd or even) and the characteristics of each may be indicated. In this case, B(=Nₛ/N̅ₛ) shortening patterns with a length of Kₛ(=QK̅ₛ) may be obtained from a quantized shortening pattern with a length of K̅ₛ such that the locations of the ones do not overlap as much as possible as shown in Table 2. Table 2 shows an algorithm for generating a shortening pattern from a quantized shortening pattern.

```
TABLE 2
Input: [symbol]
Output: [symbol]
Initialization: Set weights β₀ and β₁ s.t., 0 < β₀ < β₁ < 1
for l=1, . . . , N̅ₛ do
  Shortening pattern generation step from the lth quantized shortening pattern
  for k=1, . . . , B do
    for i=1, . . . , K̅ₛ do
      Randomly generate the partial binary sequence p_{S} [symbol]    = [p_{S} [symbol]   ] [symbol]    with
      weight Qβ [symbol]    constructed from p̅ [symbol]    s.t., mi [symbol]   (p_{S} [symbol]   p_{S} [symbol]   )
      where [symbol]    (Q,β [symbol]   ) denotes the set of length-Q binary sequences with the weight of Qβ [symbol]
    end
  end
end
Set [symbol]     = {p_{S} [symbol]   } [symbol] [symbol]
indicates data missing or illegible when filed
```

To indicate B shortening patterns based on the properties of information sequences, a method of mapping a corresponding shortening pattern to an index obtained by increasing a value obtained by applying B-modulo operation to the weight of an information sequence by 1 may be considered.

The characteristics of the learning-based algorithm for designing the shortening pattern set described above are summarized as follows.

1. To relax a training information sequence set, it is necessary to configure a quantized information sequence set.

2. It is necessary to configure a set of quantized shortening pattern sequences by relaxing a set of possible shortening pattern sequences.

3. The machine learning algorithm according to the present disclosure uses a set of quantized information sequences and a set of quantized shortening patterns as inputs.

4. The machine learning algorithm according to the present disclosure has an iterative procedure for selecting a shortening pattern and allocating the shortening pattern to an information sequence by using the minimum distance between quantized shortening pattern attached information sequences as the performance of the cost function.

(4) Learning-Based QC-LDPC Code Decoder

Since the PCM of LDPC codes has irregular degree distribution, reliability may differ between messages. In addition, QC-LDPC codes may be expressed simply in the form of a base graph (BG) (adjacent matrices) and have the advantage of inferring the operation of the BP decoder. In addition, it is possible to identify VNs that are less resilient because they belong to a trapping set on the BG (the reliability of a message from a CN connected to multiple VNs having short cycles decreases), and the delivery of messages to the corresponding VNs may need to be restricted. The present disclosure proposes as a standard BP decoder a weighted BP decoder where each message is weighted in consideration of the reliability of V2C messages and C2V messages. In the above technique, a deep learning-based learning algorithm is used to solve the optimization problem of finding the optimal weight combination.

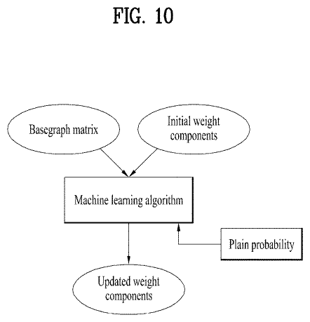

FIG. 10 is a diagram for explaining a standard BP decoding algorithm in a BS.

A machine learning algorithm may use as input for learning an initial weight component and a matrix specifying a BS and use an updated weight component as the output of the machine learning algorithm.

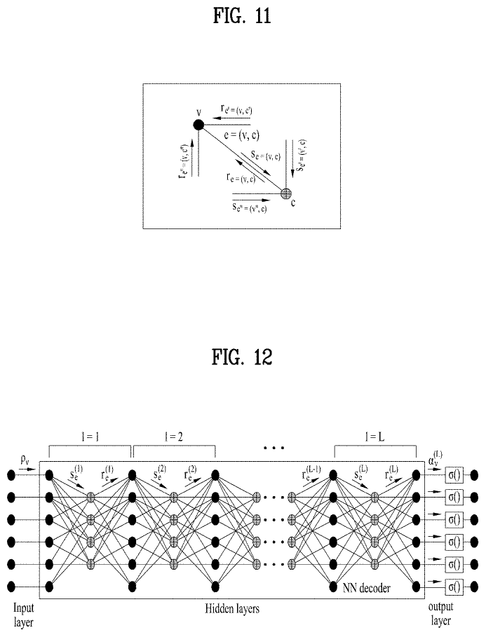

FIG. 11 is a diagram for explaining a standard BP decoding algorithm in a BS, and FIG. 12 is a diagram illustrating deep learning-based BP decoding to calculate weight components of the weighted BP decoder.

Hereinafter, an embodiment in which machine learning based on deep learning is applied to obtain weight components in the weighted BP decoder according to the present disclosure will be described. This is a supervised learning method because an all-zero codeword is given as an input/output training set. FIG. 11 shows the standard BP decoding algorithm for a general BS. The algorithm satisfies the relationship of Equations 3 to 5.

$$\begin{matrix}{s}_{e = ( v , c )}^{( l )} = tanh ( \frac{{ρ}_{v} + {\sum }_{{e}^{′} = ( v , {c}^{′} ) , {c}^{′} \neq c} {r}_{{e}^{′}}^{( l - 1 )}}{2} ) & [ Equation 3 ] \\ {r}_{e = ( v , c )}^{( l )} = 2 {tanh}^{- 1} ( {\prod }_{{e}^{′} = ( {v}^{′} , c ) {v}^{′} \neq v} {s}_{{e}^{′}}^{( l )} ) & [ Equation 4 ] \\ {a}_{v}^{( l )} = {ρ}_{v} + {\sum }_{{e}^{′} = ( v , {c}^{′} )} {r}_{{e}^{′}}^{( l )} & [ Equation 5 ]\end{matrix}$$

In Equations 3 to 5, pᵥ denotes an LLR value of VN v, s_{e=(v,c)}^{(l)} and r_{e=(v,c)}^{(l)} denotes a V2C and C2V messages of edge (v,c), and aᵥ denotes a-posterior probability (APP) message. To convert the standard BP decoding algorithm into the weighted BP decoding algorithm, Equations 3 and 5 may be expressed as shown in Equation 6.

$${a}_{v}^{( l )} = {ρ}_{v} + {\sum }_{{e}^{′} = ( v , {c}^{′} )} {w}_{v , {e}^{′}}^{( l )} {r}_{{e}^{′}}^{( l )} \qquad [ Equation 6 ]$$

To learn the weight components in the weighted BP decoder, a plain probability function obtained by filtering a sigmoid function to the LLR value of an output layer (L-th layer) as a loss function may be used (a cross entropy function is used as the loss function in the deep learning algorithm). This may be expressed as shown in Equation 7, where the sigmoid function is σ(x)=(1+e^{-x})⁻¹.

A training process for obtaining a weight combination in the weighted BP decoder through learning is shown in Table 3 below. Table 3 shows a training algorithm for weight components in a learning-based BP decoder

oᵥ=σ(aᵥ^{(l)}) [Equation 7]

```
TABLE 3
Input: ρ = [ρ_{ν}]_{ν=1}^{N}, y = [y_{ν}]_{ν=1}^{N} = 0_{N}, {w_{ν,e}⁽⁰⁾}_{νϵV,eϵE}, Π =
( [symbol]   , [symbol]    , [symbol]    ), ϵ_{cost}
Output: {w_{ν,e}^{(L)} [symbol]
Initialization: w_{v,e}⁽⁰⁾ = 1 for ∀ν ϵ [symbol]     and ∀e ϵ [symbol]
While (1)
for l=1, . . . , L do
Obtain {sₑ^{(l)}}, {rₑ^{(l)}} and {o_{ν}} by equations (6), (4) and (7)
end
Calculate cost function J(y, o)
If J(y, o) ≤ ϵ_{cost}
  Break;
Else
  for l=1, . . . , L do
Obtain {sₑ^{(l)}}, {rₑ^{(l)}} and {o_{ν}} by equations (6), (4) and (7)
For ∀e ϵ [symbol]    , w_{ν,e}^{(l)} = U(w_{ν,e}^{(l-1)}, η, J(y,o))
end
end
end
```

In Table 3, l is an iteration index and a layer index, η is a learning rate, and ϵ_{cost} is a cost function constraint. In addition, yᵥ is an actual v-th codeword element. Since training is performed using the all-zero codeword, yᵥ is set to zero.

Also,

$$J ( y , o ) = - \frac{1}{N} {\sum }_{v = 1}^{N} {y}_{v} ln ( {o}_{v} ) + ( 1 - {y}_{v} ) ln ( 1 - {o}_{v} ) = - \frac{1}{N} {\sum }_{v = 1}^{N} ln ( 1 - {o}_{v} )$$

is a logistic regression cost function, and

$$U ( {w}_{v , e}^{( l - 1 )} , η , J ( y , o ) ) = {w}_{v , e}^{( l - 1 )} - η \frac{\partial J ( y , o )}{\partial {w}_{v , e}^{( l - 1 )}}$$

is a function based on the gradient descent algorithm that updates weight components during training.

The characteristics of the learning-based algorithm for designing the weighted BP algorithm described above may be summarized as follows. The machine learning algorithm uses the BS of QC LDPC codes and the LLR of an information sequence as inputs and output the weight combination of the weighted BP decoder that reflect the reliability of each V2C message.

Based on the weight component combination obtained from the above, when the weighted BP decoder operates, VN and CN groups corresponding to the same VNs and CNs on the BS use the same weight component.

(5) Extension of Encoder/Decoder Structure to General Linear Block Code

The present disclosure has been described based on the QC-LDPC code, but the present disclosure is not limited to the QC-LDPC code. The concept of the encoder/decoder using the shortening pattern is applicable to general linear block codes. Therefore, it is also applicable to as a transmission/reception device to linear block codes of current commercial broadcast and WLAN standards.

(6) Standard Application for Encoder/Decoder Structure

To apply the encoder/decoder structure according to the present disclosure, a shortening pattern attachment process and a shortening pattern determination process based on information sequences need to be specified before CRC attachment when a transport block is generated. In addition, the weight value of each V2C message also needs to be specified when a message-passing decoder is implemented.

The above-described embodiments are combinations of elements and features of the present disclosure in prescribed forms. The elements or features may be considered as selective unless specified otherwise. Each element or feature may be implemented without being combined with other elements or features. Further, the embodiment of the present disclosure may be constructed by combining some of the elements and/or features. The order of the operations described in the embodiments of the present disclosure may be modified. Some configurations or features of any one embodiment may be included in another embodiment or replaced with corresponding configurations or features of the other embodiment. It is obvious to those skilled in the art that claims that are not explicitly cited in each other in the appended claims may be presented in combination as an embodiment of the present disclosure or included as a new claim by a subsequent amendment after the application is filed.

It will be appreciated by those skilled in the art that the present disclosure can be carried out in other specific ways than those set forth herein without departing from the essential characteristics of the present disclosure. The above embodiments are therefore to be construed in all aspects as illustrative and not restrictive. The scope of the disclosure should be determined by the appended claims and their legal equivalents, not by the above description, and all changes coming within the meaning and equivalency range of the appended claims are intended to be embraced therein.

The method of encoding and decoding low-density parity-check (LDPC) codes and communication apparatus therefor are industrially applicable to wireless communication systems such as 3GPP LTE/LTE-A and 5G systems.

1. A low-density parity-check (LDPC) encoding method for a communication device, the LDPC encoding method comprising:
generating information;
attaching a shortening pattern to the information; and
performing LDPC encoding of a sequence of the information to which the shortening pattern is attached.

2. The LDPC encoding method of claim 1, further comprising transmitting information about the shortening pattern to a receiving side.

3. The LDPC encoding method of claim 1, further comprising determining the shortening pattern from a shortening pattern set based on features of the information.

4. The LDPC encoding method of claim 3, wherein the features of the information include a feature about a weight of ones in a bit sequence corresponding to the information.

5. A low-density parity-check (LDPC) decoding method for a communication device, the LDPC decoding method comprising:
obtaining information about a shortening pattern;
performing first decoding by configuring a log-likelihood ratio (LLR) value of a shortening part based on the information about the shortening pattern; and
verifying validity of a corresponding codeword based on results of the first decoding.

6. The LDPC decoding method of claim 5, further comprising:
based on that the corresponding codeword is invalid, verifying validity of a partial codeword of the corresponding codeword;
reconfiguring the LLR value of sequences of the partial codeword estimated to be valid; and
performing second decoding of the corresponding codeword based on the reconfigured LLR value;
reconfiguring LLR values of sequences of the validated partial codeword; and
performing second decoding of the corresponding codeword based on the reconfigured LLR values.

7. The LDPC decoding method of claim 5, further comprising receiving the information about the shortening pattern from a transmitting side.

8. The LDPC decoding method of claim 5, wherein the first decoding and second decoding are learning-based belief propagation (BP) decoding.

9. The LDPC decoding method of claim 5, wherein the validity of the corresponding codeword is verified by a syndrome check for the results of the first decoding.

10. A communication device for performing low-density parity-check (LDPC) encoding, the communication device comprising:
a processor configured to generate information and attach a shortening pattern to the information; and
an LDPC encoder configured to perform the LDPC encoding of a sequence of the information to which the shortening pattern is attached.

11. The communication device of claim 10, further comprising a transmitter configured to transmit information about the shortening pattern to a receiving side.

12. The communication device of claim 10, wherein the processor is configured to determine the shortening pattern from a shortening pattern set based on features of the information.

13. The communication device of claim 12, wherein the features of the information include a feature about a weight of ones in a bit sequence corresponding to the information.

14. A communication device for performing low-density parity-check (LDPC) decoding, the communication device comprising:
a processor configured to obtain information about a shortening pattern; and
an LDPC decoder configured to perform first decoding by configuring a log-likelihood ratio (LLR) value of a shortening part based on the information about the shortening pattern and verify validity of a corresponding codeword based on results of the first decoding.

15. The communication device of claim 14, wherein the LDPC decoder is configured to:
based on that the corresponding codeword is invalid, verify validity of a partial codeword of the corresponding codeword;
reconfigure the LLR value of sequences of the partial codeword estimated to be valid; and
perform second decoding of the corresponding codeword based on the reconfigured LLR value;
reconfigure LLR values of sequences of the validated partial codeword; and
perform second decoding of the corresponding codeword based on the reconfigured LLR values.

16. The communication device of claim 14, further comprising a receiver configured to receive the information about the shortening pattern from a transmitting side.

17. The communication device of claim 14, wherein the LDPC decoder is configured to verify the validity of the corresponding codeword through a syndrome check for the results of the first decoding.
